(19) United States
(12) Patent Application Publication
(10) Pub. No.: US 2013/0057361 A1
(43) Pub. Date: Mar. 7, 2013

(54) SURFACE ACOUSTIC WAVE DEVICE AND PRODUCTION METHOD THEREFOR

(71) Applicant: MURATA MANUFACTURING CO., LTD., Nagaokakyo-shi (JP)

(72) Inventors: Kiwamu SAKANO, Nagaokakyo-shi (JP); Shu YAMADA, Nagaokakyo-shi (JP)

(73) Assignee: MURATA MANUFACTURING CO., LTD., Nagaokakyo-shi (JP)

(21) Appl. No.: 13/667,087

(22) Filed: Nov. 2, 2012

Related U.S. Application Data
(63) Continuation of application No. PCT/JP2011/052369, filed on Feb. 4, 2011.

(30) Foreign Application Priority Data
May 7, 2010 (JP) 2010-107360

(51) Int. Cl. H03H 9/05; H05K 13/00; H03H 9/17

(52) U.S. Cl. 333/193; 29/594

(57) ABSTRACT

A surface acoustic wave device includes a surface acoustic wave element including a plurality of electrode pads, and a mount substrate. The surface acoustic wave element is flip-chip mounted on a die-attach surface of the mount substrate by bumps made of Au. The mount substrate includes at least one resin layer including via-holes, a plurality of mount electrodes provided on the die-attach surface of the mount substrate, and via-hole conductors. The mount electrodes are bonded to the electrode pads via the bumps. The via-hole conductors are provided in the via-holes. At least one of each of the electrode pads and each of the mount electrodes includes a front layer made of Au. At least one of the via-hole conductors is located below the corresponding bump.

### BACKGROUND OF THE INVENTION

1. Field of the Invention

The present invention relates to a surface acoustic wave device and a production method therefor. More particularly, the present invention relates to a Chip Size Package (CSP) surface acoustic wave device in which a surface acoustic wave element is flip-chip mounted on a mount substrate, and to a production method therefor.

2. Description of the Related Art

Surface acoustic wave devices have been installed in Radio Frequency (RF) circuits of communication apparatuses such as mobile telephones. In recent years, the communication apparatuses have been sophisticated and reduced in size and weight, and the surface acoustic wave devices installed in the RF circuits are also requested to be reduced in size, weight, and profile. As a surface acoustic wave device that meets such requirements, a CSP surface acoustic wave device has been put to practical use.

A CSP surface acoustic wave device includes a surface acoustic wave element and a mount substrate. The surface acoustic wave element includes a piezoelectric substrate, at least one IDT electrode, and a plurality of electrode pads connected to the at least one IDT electrode. The at least one IDT electrode and the electrode pads are provided on the piezoelectric substrate. A plurality of mount electrodes are provided on a die-attach surface of the mount substrate. The surface acoustic wave element is flip-chip mounted on the die-attach surface of the mount substrate with the electrode pads being bonded to the mount electrodes by bumps. The surface acoustic wave element is sealed by a sealing resin layer provided on the mount substrate.

An example of such a CSP surface acoustic wave device is described in Japanese Unexamined Patent Application Publication No. 2006-128809 described below. Japanese Unexamined Patent Application Publication No. 2006-128809 describes that bumps are formed of Au, that a surface acoustic wave element is ultrasonically bump-bonded to a mount substrate, and that a resin substrate is used as the mount substrate.

However, in the CSP surface acoustic wave device described in Japanese Unexamined Patent Application Publication No. 2006-128809, it is impossible to achieve a sufficiently high bonding strength between the surface acoustic wave element and the mount substrate.

### SUMMARY OF THE INVENTION

Accordingly, preferred embodiments of the present invention provide a CSP surface acoustic wave device in which a surface acoustic wave element is flip-chip mounted on a mount substrate and in which the bonding strength between the surface acoustic wave element and the mount substrate is high.

A surface acoustic wave device according to a preferred embodiment of the present invention includes a surface acoustic wave element and a mount substrate. The surface acoustic wave element includes a plurality of electrode pads. The surface acoustic wave element is flip-chip mounted on a die-attach surface serving as one surface of the mount substrate by bumps made of Au. The mount substrate includes at least one resin layer, a plurality of mount electrodes, and via-hole conductors. The resin layer includes via-holes. The mount electrodes are provided on the die-attach surface of the mount substrate. The mount electrodes are bonded to the electrode pads by the bumps. The via-hole conductors are provided in the via-holes. At least one of each of the electrode pads and each of the mount electrodes includes a front layer made of Au. At least one of the via-hole conductors is located below the bump.

According to a specific aspect of the surface acoustic wave device according to a preferred embodiment of the present invention, at least one of the via-hole conductors is located below a bonded portion between the corresponding mount electrode and the corresponding electrode pad to the bump.

According to another specific aspect of the surface acoustic wave device according to a preferred embodiment of the present invention, at least one of the via-hole conductors is aligned with the bump, the corresponding mount electrode, and the corresponding electrode pad, when viewed in a mount direction of the surface acoustic wave element on the mount substrate.

According to a further specific aspect of the surface acoustic wave device according to a preferred embodiment of the present invention, the mount substrate includes a plurality of terminal electrodes and a line. The terminal electrodes are provided on the other surface of the mount substrate. The line connects the mount electrodes and the terminal electrodes. The via-hole conductors define a portion of the line.

According to an even further specific aspect of the surface acoustic wave device according to a preferred embodiment of the present invention, the resin layer is made of a resin composition containing resin, and a glass transition temperature (Tg) of the resin is within a range of about 100° C. to about 300° C. In this case, the present invention is applied more suitably.

According to a still further specific aspect of the surface acoustic wave device according to a preferred embodiment of the present invention, the resin layer is a glass epoxy resin layer made of glass epoxy in which a glass woven cloth is impregnated with epoxy resin.

According to an even still further specific aspect of the surface acoustic wave device according to a preferred embodiment of the present invention, the mount electrodes are made of Au, and each of the mount electrodes includes a laminated body of an Au layer that defines a front layer and a Ni layer made of Ni. By providing the Ni layer, the rigidity of the mount electrodes can be increased. Therefore, the bonding strength between the surface acoustic wave element and the mount electrode can be increased further.

According to an even still further specific aspect of the surface acoustic wave device according to a preferred embodiment of the present invention, the laminated body includes a plurality of plated layers containing the Ni layer, and the Ni layer has the largest thickness among the plated layers. This structure can further increase the rigidity of the mount electrodes. Therefore, the bonding strength between the surface acoustic wave element and the mount substrate can be increased further.

According to an even still further specific aspect of the surface acoustic wave device according to a preferred embodiment of the present invention, the via-hole conductors are made of Cu. This structure can more effectively prevent the via-hole conductors from deforming when the surface acoustic wave device is produced by flip-chip mounting. Therefore, the bonding strength between the surface acoustic wave element and the mount substrate can be increased further.

According to an even still further specific aspect of the surface acoustic wave device according to a preferred embodiment of the present invention, the mount substrate includes a plurality of terminal electrodes provided on the other surface of the mount substrate, and a line that connects the mount electrodes and the terminal electrodes. The line is provided in a portion of the die-attach surface of the mount substrate other than an area opposing a piezoelectric substrate of the surface acoustic wave element. This structure can prevent the surface acoustic wave element from being damaged when the surface acoustic wave device is produced by flip-chip mounting. Therefore, the surface acoustic wave device can be produced at a high yield.

According to an even still further specific aspect of the surface acoustic wave device according to a preferred embodiment of the present invention, the surface acoustic wave device further includes a sealing resin layer provided on the mount substrate to seal the surface acoustic wave element. This structure can protect the surface acoustic wave element.

A production method for a surface acoustic wave device according to another preferred embodiment of the present invention relates to a method for producing the above-described surface acoustic wave device according to a preferred embodiment of the present invention. In the production method for the surface acoustic wave device according to a preferred embodiment of the present invention, the surface acoustic wave element is flip-chip mounted on the mount substrate by applying a load to the surface acoustic wave element in a direction to bring the mount substrate and the surface acoustic wave element closer to each other and applying ultrasonic waves to the surface acoustic wave element while heating the bumps and the mount electrodes, or the bumps and the electrode pads in a state in which the bumps are in contact with the mount electrodes or the bumps are in contact with the electrode pads.

According to a specific aspect of the production method for the surface acoustic wave device according to a preferred embodiment of the present invention, the bumps and the mount electrodes, or the bumps and the electrode pads are heated to a temperature higher than or equal to a recrylstallization temperature of Au when the surface acoustic wave element is flip-chip mounted on the mount substrate.

In various preferred embodiments of the present invention, at least one of the via-hole conductors is located below the corresponding bump. For this reason, the mount electrodes and the bumps, or the electrode pads and the bumps can be metallically bonded firmly and securely. As a result, it is possible to obtain a surface acoustic wave device in which the bonding strength between a surface acoustic wave element and a mount substrate is high.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic sectional view of a surface acoustic wave device according to a preferred embodiment of the present invention.

FIG. 2 is a partly enlarged schematic sectional view of a section II in FIG. 1.

FIG. 3 is a schematic transparent plan view of a surface 12a1 of a first resin layer 12a of a mount substrate 10 in a surface acoustic wave device according to a first example of a preferred embodiment of the present invention.

FIG. 4 is a schematic transparent plan view of a surface 12b1 of a second resin layer 12b of the mount substrate in the surface acoustic wave device according to the first example of a preferred embodiment of the present invention.

FIG. 5 is a schematic transparent plan view of a surface 12c1 of a third resin layer 12c of the mount substrate 10 in the surface acoustic wave device according to the first example of a preferred embodiment of the present invention.

FIG. 6 is a schematic transparent plan view of a surface 12c2 of the third resin layer 12c of the mount substrate in the surface acoustic wave device according to the first example of a preferred embodiment of the present invention.

FIG. 7 is a schematic sectional view of the surface acoustic wave device according to the first example of a preferred embodiment of the present invention, taken along line VII-VII of FIG. 3.

FIG. 8 is a schematic transparent plan view of a surface 12a1 of a first resin layer 12a of a mount substrate 10 in a surface acoustic wave device according to a first comparative example.

FIG. 9 is a schematic transparent plan view of a surface 12b1 of a second resin layer 12b of the mount substrate in the surface acoustic wave device according to the first comparative example.

FIG. 10 is a schematic transparent plan view of a surface 12c1 of a third resin layer 12c of the mount substrate 10 in the surface acoustic wave device according to the first comparative example.

FIG. 11 is a schematic transparent plan view of a surface 12c2 of the third resin layer 12c of the mount substrate in the surface acoustic wave device according to the first comparative example.

FIG. 12 is a schematic sectional view of the surface acoustic wave device according to the first comparative example, taken along line XII-XII of FIG. 8.

FIG. 13 is a graph showing die shear strengths of the surface acoustic wave device of the first example of a preferred embodiment of the present invention and the surface acoustic wave device of the first comparative example.

FIG. 14 is a graph showing bump shear strengths of the surface acoustic wave device of the first example of a preferred embodiment of the present invention and the surface acoustic wave device of the first comparative example.

FIG. 15 is a schematic sectional view of a surface acoustic wave device according to a first modification of a preferred embodiment of the present invention.

FIG. 16 is a schematic sectional view of a surface acoustic wave device according to a second modification of a preferred embodiment of the present invention.

FIG. 17 is a schematic sectional view of a surface acoustic wave device according to a third modification of a preferred embodiment of the present invention.

FIG. 18 is a schematic sectional view of a surface acoustic wave device according to a fourth modification of a preferred embodiment of the present invention.

FIG. 19 is a schematic sectional view of a surface acoustic wave device according to a fifth modification of a preferred embodiment of the present invention.

FIG. 20 is a schematic sectional view of a surface acoustic wave device according to a sixth modification of a preferred embodiment of the present invention.

FIG. 21 is a schematic sectional view of a surface acoustic wave device according to a seventh modification of a preferred embodiment of the present invention.

FIG. 22 is a schematic sectional view of a surface acoustic wave device according to an eighth modification of a preferred embodiment of the present invention.

FIG. 23 is a schematic sectional view of a surface acoustic wave device according to a ninth modification of a preferred embodiment of the present invention.

FIG. 24 is a schematic sectional view of a surface acoustic wave device according to a tenth modification of a preferred embodiment of the present invention.

FIG. 25 is a schematic plan view of a die-attach surface 10a of a mount substrate 10 in a surface acoustic wave device according to a second preferred embodiment of the present invention.

FIG. 26 is a schematic plan view of a die-attach surface 110a of a mount substrate 110 in a surface acoustic wave device according to a reference example.

FIG. 27 is a schematic plan view of a die-attach surface 10a of a mount substrate 10 in a surface acoustic wave device according to an eleventh modification of a preferred embodiment of the present invention.

FIG. 28 is a schematic plan view of a motherboard 50 for producing the mount substrate 10 in the surface acoustic wave device according to the second preferred embodiment of the present invention.

FIG. 29 is a schematic plan view of a motherboard 50 for producing a mount substrate 10 in a surface acoustic wave device according to a twelfth modification of a preferred embodiment of the present invention.

### DETAILED DESCRIPTION OF THE PREFERRED EMBODIMENTS

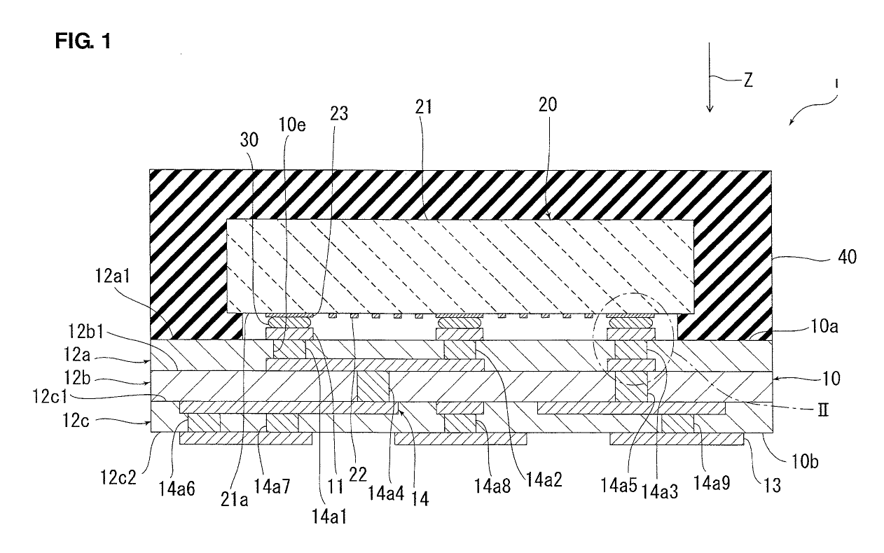

Preferred embodiments of the present invention will be described below by taking a surface acoustic wave device 1 illustrated in FIG. 1 as an example. However, the surface acoustic wave device 1 is just exemplary. A surface acoustic wave device according to the present invention is not limited by the surface acoustic wave device 1.

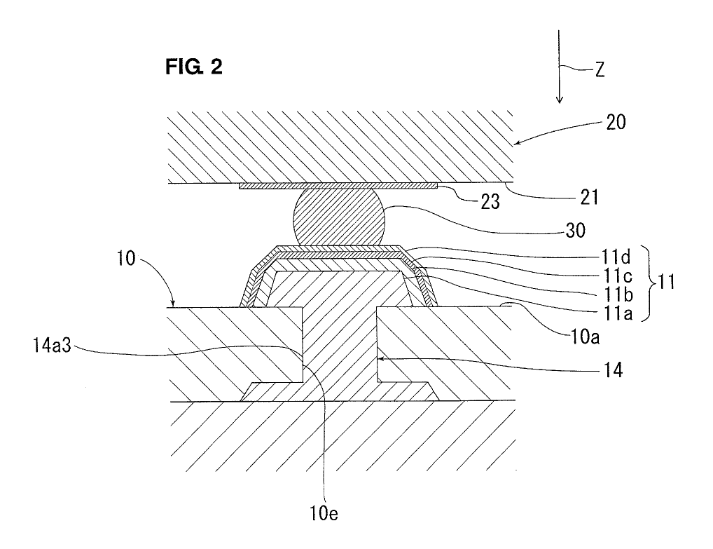

FIG. 1 is a schematic sectional view of the surface acoustic wave device 1 according to the preferred embodiment of the present invention. FIG. 2 is a partly enlarged schematic sectional view of a section II in FIG. 1.

The surface acoustic wave device 1 according to the present preferred embodiment is a CSP (Chip Size Package) surface acoustic wave device. As illustrated in FIG. 1, the surface acoustic wave device 1 includes a mount substrate 10 and a surface acoustic wave element 20 flip-chip mounted on a die-attach surface 10a of the mount substrate 10. The surface acoustic wave element 20 is sealed by a sealing resin layer 40 provided on the mount substrate 10. For example, the sealing resin layer 40 can be made of an appropriate resin such as epoxy resin.

In an area where the surface acoustic wave element 20 and the mount substrate 10 oppose each other, that is, an area where a surface acoustic wave propagates, the sealing resin layer 40 is not provided, but a space is ensured.

For example, the surface acoustic wave device 1 may be a surface acoustic wave resonator, a surface acoustic wave filter, or a surface acoustic wave duplexer.

The surface acoustic wave element 20 includes a piezoelectric substrate 21. As the piezoelectric substrate 21, a substrate made of an appropriate piezoelectric material can be used. Specifically, for example, an LiNbO₃ substrate, an LiTaO₃ substrate, or a quartz substrate can be used as the piezoelectric substrate 21.

On a mount substrate 10 side surface 21a of the piezoelectric substrate 21, at least one IDT electrode 22 and a plurality of electrode pads 23 are provided. The IDT electrode includes a pair of comb-shaped electrodes that are interdigitated with each other. For example, the IDT electrode 22 can be made of a metal selected from a group consisting of Pt, Au, Ag, Cu, Ni, W, Ta, Fe, Cr, Al, and Pd, or an alloy including one or more metals selected from a group consisting of Pt, Au, Ag, Cu, Ni, W, Ta, Fe, Cr, Al, and Pd. Alternatively, the IDT electrode 22 can include a laminated body of a plurality of conductive films made of the above-described metal or alloy.

A plurality of electrode pads 23 are electrically connected to at least one IDT electrode 22. Similarly to the IDT electrode 22, for example, the electrode pads 23 can also be made of a metal selected from a group consisting of Pt, Au, Ag, Cu, Ni, W, Ta, Fe, Cr, Al, and Pd, or an alloy including one or more metals selected from a group consisting of Pt, Au, Ag, Cu, Ni, W, Ta, Fe, Cr, Al, and Pd. Alternatively, the electrode pads 23 each can include a laminated body of a plurality of conductive films made of the above-described metal or alloy.

Bumps 30 are provided on the respective electrode pads 23. The electrode pads 23 are bonded via the bumps 30 to mount electrodes 11 provided on the die-attach surface 10a of the mount substrate 10 described below. That is, the electrode pads 23 are electrically and mechanically connected to the mount electrodes 11 provided on the die-attach surface 10a of the mount substrate by the bumps 30. In this way, the surface acoustic wave element 20 is flip-chip mounted on the die-attach surface 10a of the mount substrate 10. In the present preferred embodiment, the bumps 30 are preferably made of Au, for example.

The mount substrate 10 preferably is a resin substrate including first to third resin layers 12a to 12c. Specifically, in the present preferred embodiment, the mount substrate 10 is a resin substrate including a laminated body including the first to third resin layers 12a to 12c. While the first to third resin layers 12a to 12c can be made of an appropriate resin, when they are formed of a resin composition containing resin having a glass transition temperature (Tg) within the range of 100° C. to 300° C., below-described advantages of the present preferred embodiment are greatly exerted. Specifically, for example, the first to third resin layers 12a to 12c can include glass epoxy resin layers made of glass epoxy in which a glass woven cloth is impregnated with epoxy resin. The glass transition temperature (Tg) of the glass epoxy resin layers is preferably about 230° C., for example.

In the description of preferred embodiments of the present invention, the glass transition temperature (Tg) refers to a value measured by DMA.

A plurality of mount electrodes 11 are provided on the die-attach surface 10a of the mount substrate 10. At least a front layer of each of the mount electrodes 11 is preferably made of Au. Specifically, in the present preferred embodiment, each of the mount electrodes 11 includes a laminated body including an Au layer 11d made of Au to define the front layer of the mount electrode 11 and a Ni layer 11b made of Ni, as illustrated in FIG. 2. Since the front layer of the mount electrode 11 includes the Au layer 11d made of Au, the mount electrode 11 is bonded to the corresponding bump 30 of Au by Au—Au bonding (metallic bonding).

More specifically, each mount electrode 11 includes a laminated body in which a Cu layer 11a made of Cu, the Ni layer 11b, a Pd layer 11c made of Pd, and the Au layer 11d are stacked in this order from a mount substrate 10 side. Of these layers, the Ni layer 11b, the Pd layer 11c, and the Au layer 11d, excluding the Cu layer 11a, are preferably defined by plated layers. More specifically, the Ni layer 11b, the Pd layer 11c, and the Au layer 11d are preferably defined by electroless plated layers. In the present preferred embodiment, the Ni layer 11b has the largest thickness among the Ni layer 11b, the Pd layer 11c, and the Au layer 11d defined by electroless plated layers. The Cu layer 11a may be partially defined by a plated layer.

Preferably, the thickness of the Au layer 11d is about 0.02 μm to about 0.07 μm, for example. If the Au layer 11d is too thin, the bonding strength between the mount electrode 11 and the bump 30 is sometimes low. In contrast, if the Au layer 11d is too thick, AuSn₄ is likely to be produced when the surface acoustic wave device is mounted, with solder containing Sn, on a substrate that defines an RF circuit in a communication apparatus. This sometimes reduces the bonding strength between the surface acoustic wave device and the substrate.

The Pd layer 11c functions as a diffusion preventing layer that prevents diffusion of the electrode material between the Au layer 11d and the Ni layer 11b. It is satisfactory as long as the thickness of the Pd layer 11c is enough to sufficiently prevent diffusion of the electrode material between the Au layer 11d and the Ni layer 11b, and is preferably about 0.01 μm to about 0.05 μm, for example.

Preferably, the thickness of the Ni layer 11b is about 5 μm to about 15 μm, for example. The Ni layer 11b has the highest hardness among resin, Cu, Au, Pd, and Ni serving the materials of the first to third resin layers 12a to 12c and the mount electrodes 11. For this reason, the hardness of the mount electrodes 11 can be increased by increasing the thickness of the Ni layer 11b, as in the present preferred embodiment. Therefore, the bonding strength between the bumps 30 and the mount electrodes 11 can be increased further. If the Ni layer 11b is too thin, the bonding strength between the bumps 30 and the mount electrodes 11 sometimes becomes low.

Preferably, the Ni layer 11b is defined by an electroless Ni plated layer, as in the present preferred embodiment. Since the hardness of the Ni layer 11b can be further increased in this case, the bonding strength between the bumps 30 and the mount electrodes 11 can be increased further. The bumps 30 may be provided on the mount electrodes 11, not on the electrode pads 23. In this case, at least front layers of the electrode pads 23 are preferably made of Au. Since the front layers of the electrode pads 23 are preferably made of Au, the electrode pads 23 are bonded to the bumps 30 of Au by Au—Au bonding (metallic bonding).

As illustrated in FIG. 1, a plurality of terminal electrodes 13 are provided on the other surface of the mount substrate 10, that is, a back surface 10b of the mount substrate 10. The terminal electrodes 13 are connected to the RF circuit of the communication apparatus in which the surface acoustic wave device 1 is installed. The terminal electrodes 13 can be made of an appropriate conductive material. Specifically, the terminal electrodes 13 preferably have the same structure as that of the mount electrodes 11. More specifically, each of the terminal electrodes 13 preferably includes a laminated body in which a Cu layer made of Cu, a Ni layer made of Ni, a Pd layer made of Pd, and an Au layer made of Au are stacked in this order from the mount substrate 10 side.

A line 14 is provided in the mount substrate 10. The line 14 electrically connects the mount electrodes 11 and the terminal electrodes 13. The line 14 is provided on the die-attach surface 10a of the mount substrate 10 on which the mount electrodes 11 are provided, and inside the mount substrate 10.

The line 14 can be made of an appropriate conductive material. Specifically, for example, the line 14 can be made of Cu or an alloy containing Cu.

The line 14 includes via-hole conductors 14a1 to 14a9 provided in a plurality of via holes 10e extending through the first to third resin layers 12a to 12c of the mount substrate 10. In other words, the via-hole conductors 14a1 to 14a9 define a portion of the line 14.

In the surface acoustic wave device 1 of the present preferred embodiment, at least one of the via-hole conductors 14a1 to 14a9 is located below the corresponding bump 30. In the surface acoustic wave device 1 of the present preferred embodiment, at least one of the via-hole conductors 14a1 to 14a9 is located below a bonded portion where the mount electrode 11 and the electrode pad 23 are bonded to the corresponding bump 30. Further, in the surface acoustic wave device 1 of the present preferred embodiment, at least one of the via-hole conductors 14a1 to 14a9 is aligned with the bump 30, the mount electrode 11, and the electrode pad 23 corresponding thereto, when viewed in a mount direction z in which the surface acoustic wave element 20 is mounted on the mount substrate 10 (the mount direction z is the same as a normal direction of the die-attach surface 10a of the mount substrate 10 in the present preferred embodiment).

Next, a description will be given of a non-limiting example of a production method for the surface acoustic wave device 1 according to a preferred embodiment of the present invention.

First, bumps 30 are formed on a plurality of electrode pads 23 of a surface acoustic wave element 20. A method for forming the bumps 30 is not particularly limited. For example, the bumps 30 can be formed by a stud bump method.

By performing a bonding step of bonding the bumps 30 provided on the electrode pads 23 in the surface acoustic wave element 20 to mount electrodes 11 in a mount substrate 10, the surface acoustic wave element 20 is flip-chip mounted on a die-attach surface 10a of the mount substrate 10. Then, a surface acoustic wave device 1 is finished by sealing the surface acoustic wave element 20 by a sealing resin layer 40. Specifically, a load is applied to the surface acoustic wave element 20 in a direction to bring the mount substrate 10 and the surface acoustic wave element 20 closer to each other and an ultrasonic wave is applied thereto while heating the mount electrodes 11 of the mount substrate 10 and the bumps 30 provided on the electrode pads 23 of the surface acoustic wave element 20 in a state in which the bumps 30 are in contact with the mount electrodes 11. Thus, Au atoms in Au layers 11d of the mount electrodes 11 are forcibly brought closer to Au atoms in the bumps 30. As a result, the Au atoms in the Au layers 11d of the mount electrodes 11 and the Au atoms in the bumps 30 are bonded metallically. That is, the bumps 30 and the mount electrodes 11 are subjected to Au—Au bonding (metallic bonding). The bumps 30 may be formed on the mount electrodes 11, not on the electrode pads 23. In this case, after the bumps 30 are formed on the mount electrodes 11, a bonding step is performed to bond the bumps 30 provided on the mount electrodes 11 to the electrode pads 23 having at least front layers formed of Au, thereby flip-chip mounting the surface acoustic wave element 20 on the die-attach surface 10a of the mount substrate 10. Specifically, a load is applied to the surface acoustic wave element 20 in a direction to bring the mount substrate 10 and the surface acoustic wave element 20 closer to each other and an ultrasonic wave is applied thereto while heating the electrode pads 23 and the bumps 30 provided on the mount electrodes 11 in a state in which the bumps 30 are in contact with the electrode pads 23. Thus, Au atoms in the front layers of the electrode pads 23 are forcibly brought closer to the Au bumps in the bumps 30. As a result, the Au atoms in the front layers of the electrode pads 23 and the Au atoms in the bumps 30 are metallically bonded. That is, the bumps 30 and the electrode pads 23 are bonded by Au—Au bonding (metallic bonding).

To properly achieve Au—Au bonding (metallic bonding), it is preferable that the load applied to the surface acoustic wave element 20 should be heavy. This is because the Au atoms in the Au layers 11d of the mount electrodes 11 or in the front layers of the electrode pads 23 can be brought even closer to the Au atoms in the bumps 30 by increasing the load applied to the surface acoustic wave element 20, and therefore, metallic bonding easily occurs. However, if the load applied to the surface acoustic wave element 20 is too heavy, the surface acoustic wave element 20 is sometimes damaged.

In the bonding step, the mount electrodes 11 or the electrode pads 23, and the bumps 30 are preferably heated to a temperature higher than or equal to a recrystallization temperature of Au. In this case, since the Au atoms easily move, stronger metallic bonding can be achieved. Specifically, in the bonding step, the mount electrodes 11 or the electrode pads 23, and the bumps 30 are heated to about 200° C. or more, for example. However, if the mount electrodes 11 or the electrode pads 23, and the bumps 30 are excessively heated to a high temperature, the mount substrate 10 and the surface acoustic wave element 20 are sometimes damaged. Therefore, it is preferable that a heating temperature for the mount electrodes 11 or the electrode pads 23, and the bumps 30 should be about 300° C. or less, for example.

In a CSP surface acoustic wave device of the related art, a ceramic substrate, such as an LTCC (Low Temperature Co-fired Ceramics) substrate or an HTCC (High Temperature Cofired Ceramics) substrate is generally used as a mount substrate.

In contrast, in the present preferred embodiment, the mount substrate 10 is a resin substrate including a laminated body of the first to third resin layers 12a to 12c. That is, the mount substrate 10 is preferably made of resin. Therefore, the following advantages (1) to (3) can be obtained.

(1) An Excellent Electric Characteristic can be Obtained.

In a ceramic substrate, an electrode is formed by firing conductive paste printed on a ceramic green sheet. For this reason, the print accuracy and contraction due to firing of the conductive paste make it difficult to form a fine electrode with high precision.

In contrast, in the mount substrate 10 formed by a resin substrate, an electrode can be formed by patterning a metal layer formed on a resin layer by etching or other methods. For this reason, in the mount substrate 10 formed by the resin substrate, a fine electrode can be formed with high precision. Hence, in the mount substrate 10 formed by the resin substrate, the numbers of electrodes and via-holes that can be formed per unit area are larger than in the ceramic substrate. Therefore, the degree of flexibility in design is increased, and an excellent electric characteristic can be obtained.

Further, an electrode is formed by firing on the ceramic substrate, as described above. For this reason, the cross-sectional shape of the electrode formed on the ceramic substrate is crushed at an edge. In contrast, on the case of the mount substrate 10 formed by the resin substrate, an electrode can be formed by patterning a metal layer, for example, by etching. For this reason, the cross-sectional shape of the electrode formed on the mount substrate 10 of the resin substrate is similar to a trapezoid or a rectangle. Hence, the loss of a radio frequency signal is less in the electrode on the mount substrate 10 of the resin substrate because the conductor loss due to the edge effect is reduced. In this point, an excellent electric characteristic can also be obtained.

On the mount substrate 10 formed by the resin substrate, an electrode material having an electrical conductivity higher than in an HTCC substrate can be used. Since an electrode is formed by firing conductive paste printed on a ceramic green sheet at a high temperature of about 1600° C. in the HTCC substrate, it is necessary to use a high-melting-point metal such as W, Mo, or Ta as the electrode material. However, electrical conductivities of these high-melting-point metals are low. For this reason, it is difficult to form an electrode having a high electrical conductivity in the HTCC substrate. In contrast, in the mount substrate 10 of the resin substrate, firing is unnecessary for formation of the electrode, and therefore, a metal having a high electrical conductivity, such as Cu, can be used as the electrode material. Therefore, on the mount substrate 10 of the resin substrate, an electrode having a high electrical conductivity can be formed, and the loss of a radio frequency signal at the electrode can be reduced. In this point, an excellent electric characteristic can also be obtained.

On the mount substrate 10 formed by the resin substrate, an electrode having an electrode density higher than on the LTCC substrate can be formed. Since the firing temperature of the LTCC substrate is a low temperature of about 850° C. to about 900° C., a metal having a high electrical conductivity, such as Cu, can be used as the electrode material. However, since an electrode is formed by firing conductive paste printed on a ceramic green sheet in the LTCC substrate, the electrode is partially cracked by firing, and a portion having a low electrode density and a portion having a high electrode density are mixed. In contrast, since an electrode is formed by patterning a metal layer by, for example, etching in the mount substrate 10 of the resin substrate, an electrode having a uniform and high electrode density can be formed. As a result, in the mount substrate 10 of the resin substrate, the loss of a radio frequency signal in the electrode can be reduced. In this point, an excellent electrical characteristic can also be obtained.

(2) A High Thermal Shock Resistance can be Obtained.

As described above, a piezoelectric substrate, such as an LiTaO₃ substrate or an LiNbO₃ substrate, is used as a piezoelectric substrate in a surface acoustic wave element. The linear expansion coefficient in the planar direction of the LiTaO₃ substrate or the LiNbO₃ substrate is about 15 ppm/° C. to about 16 ppm/° C. In contrast, the linear expansion coefficient in the planar direction of the ceramic substrate is about 7 ppm/° C., and this is almost half the linear expansion coefficient in the planar direction of the piezoelectric substrate. For this reason, in a CSP surface acoustic wave device using a ceramic substrate as a mount substrate, when a temperature cyclic load is applied, stress is produced in a bonded portion between a surface acoustic wave element and the mount substrate because of differences in expansion amount and contraction amount between a piezoelectric substrate of the surface acoustic wave element and the ceramic substrate serving as the mount substrate. As a result, the bonding strength at the bonded portion decreases. That is, it is difficult to obtain a sufficiently high thermal shock resistance. This problem is pronounced when the bumps are formed of Au.

In contrast, the linear expansion coefficient in the planar direction of the mount substrate 10, which is formed by a laminated body of the first to third resin layers 12a to 12c made of, for example, glass epoxy, is about 13 ppm/° C. to about 16 ppm/° C., and this is substantially equal to the linear expansion coefficient in the planar direction of the piezoelectric substrate. For this reason, stress produced in the bonded portion between the surface acoustic wave element 20 and the mount substrate 10 decreases, and a high thermal shock resistance can be obtained.

(3) It is Possible to Increase the Coplanarity of the Die-Attach Surface 10a of the Mount Substrate 10.

Since a ceramic substrate contracts during firing, a surface thereof is likely to be distorted. In contrast, since the mount substrate 10 formed by a resin substrate can be formed by pressing, a surface having high coplanarity can be easily obtained. That is, it is possible to achieve high coplanarity of the die-attach surface 10a of the mount substrate 10. As a result, the bonding strength between the surface acoustic wave element 20 and the mount substrate 10 can be increased.

However, the resin substrate has a glass transition temperature (Tg) lower than the melting point of the ceramic substrate and the like. For example, the glass transition temperature (Tg) of resin, such as glass epoxy, is within the range of about 100° C. to 300° C. For this reason, in a CSP surface acoustic wave device using a resin substrate as a mount substrate, if mount electrodes or electrode pads, each having a front layer of Au, and bumps formed of Au are heated for Au—Au bonding (metallic bonding) to a temperature higher than or equal to 200° C. that is higher than or equal to the recrystallization temperature of Au, the resin substrate softens. When the resin substrate softens, the load and the force of ultrasonic vibration are released without being applied to the mount electrodes and the bumps. For this reason, the Au atoms in the mount electrodes or the electrode pads and the Au atoms in the bumps are not easily brought close to each other where they are metallically bonded. Therefore, strong Au—Au bonding (metallic bonding) cannot be obtained between the mount electrodes or the electrode pads, and the bumps, and bonding of the surface acoustic wave element and the mount substrate sometimes becomes insufficient.

In contrast, in the surface acoustic wave device 1 of the present preferred embodiment, at least one of the via-hole conductors 14a1 to 14a9 is located below the corresponding bump 30. In the surface acoustic wave device 1 of the present preferred embodiment, at least one of the via-hole conductors 14a1 to 14a9 is located below the bonded portion between the mount electrode 11 and the electrode pad 23, and the bump 30 corresponding thereto. Further, in the surface acoustic wave device 1 of the present preferred embodiment, at least one of the via-hole conductors 14a1 to 14a9 is aligned with the bump 30, the mount electrode 11, and the electrode pad 23, when viewed in the mount direction z in which the surface acoustic wave element 20 is mounted on the mount substrate 10. Here, since the via-hole conductors 14a1 to 14a9 are formed of metal or an alloy, they have a melting point higher than the glass transition temperature (Tg) of resin that forms the first to third resin layers 12a to 12c in the mount substrate 10 of the resin substrate. Therefore, in the bonding step of bonding the bumps 30 formed on the electrode pads 23 of the surface acoustic wave element 20 to the mount electrodes 11 of the mount substrate 10, or bonding the bumps 30 formed on the mount electrodes 11 of the mount substrate 10 to the electrode pads 23 of the surface acoustic wave element 20, even when the via-hole conductors 14a1 to 14a9 are heated to a temperature higher than or equal to 200° C. that is higher than or equal to the recrystallization temperature of Au, they do not easily soften. In particular, since the melting point of Cu is 1084.4° C., when the via-hole conductors 14a1 to 14a9 are formed of Cu, they are more unlikely to soften. Hence, since the via-hole conductors 14a1 to 14a9 function as support members, even if the mount substrate 10 formed by the resin substrate softens, the load and the force of ultrasonic vibration are properly applied between the mount electrodes 11 or the electrode pads 23, and the bumps 30. As a result, the mount electrodes 11 or the electrode pads 23, can be firmly and securely bonded to the bumps 30 by Au—Au bonding (metallic bonding). As a result, it is possible to obtain the surface acoustic wave device 1 in which the bonding strength between the surface acoustic wave element 20 and the mount substrate 10 is high.

### First Example

The advantages of the above-described preferred embodiment will be more specifically described below on the basis of a first example of a preferred embodiment of the present invention and a first comparative example. In descriptions of the first example and the first comparative example, members having functions substantially common to the above preferred embodiment are denoted by common reference numerals, and descriptions thereof are skipped.

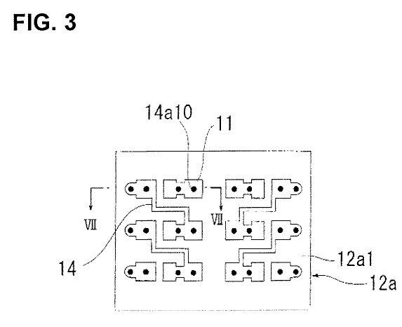

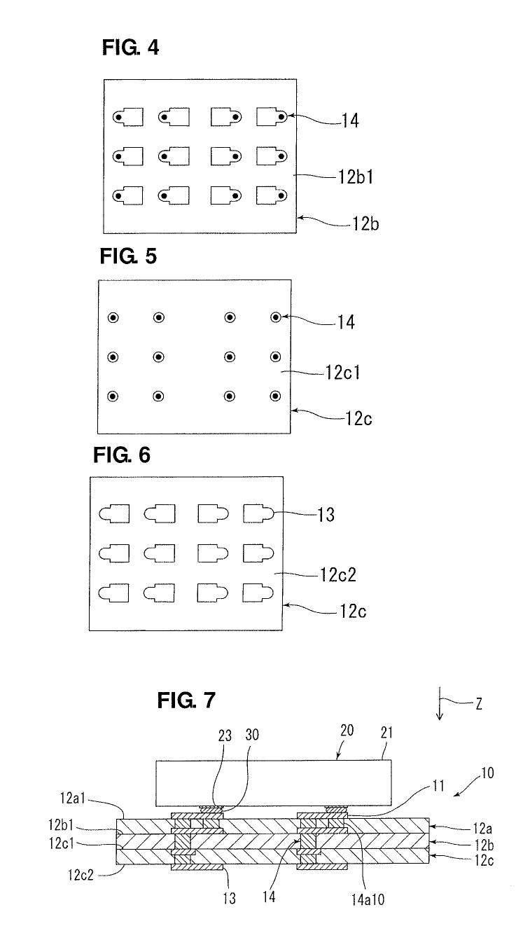

FIG. 3 is a schematic transparent plan view of a surface 12a1 of a first resin layer 12a of a mount substrate 10 in a surface acoustic wave device according to a first example of a preferred embodiment of the present invention. FIG. 4 is a schematic transparent plan view of a surface 12b1 of a second resin layer 12b of the mount substrate 10 in the surface acoustic wave device according to the first example of a preferred embodiment of the present invention. FIG. 5 is a schematic transparent plan view of a surface 12c1 of a third resin layer 12c of the mount substrate 10 in the surface acoustic wave device according to the first example of a preferred embodiment of the present invention. FIG. 6 is a schematic transparent plan view of a surface 12c2 of the third resin layer 12c of the mount substrate 10 in the surface acoustic wave device according to the first example of a preferred embodiment of the present invention. FIG. 7 is a schematic sectional view of the surface acoustic wave device according to the first example of a preferred embodiment of the present invention, taken along line VII-VII of FIG. 3. The surface 12a1 of the first resin layer 12a of the mount substrate 10 is a die-attach surface 10a serving as one surface of the mount substrate 10. On the surface 12a1 of the first layer 12a of the mount substrate 10, a plurality of mount electrodes 11 and portions of a line 14 are provided. The mount electrodes are connected to one another by the portions of the line 14.

As the first example of a preferred embodiment of the present invention, a surface acoustic wave device having structures illustrated in FIGS. 3 to 7 was prepared. As illustrated in FIGS. 3 and 7, in the surface acoustic wave device of the first example, a via-hole conductor 14a10 is provided below a bump 30. In the surface acoustic wave device of the first example, the via-hole conductor 14a10 is provided below a bonded portion of a mount electrode 11 and an electrode pad 23 to the bump 30. Further, in the surface acoustic wave device of the first example, the via-hole conductor 14a10 is aligned with the bump 30, the mount electrode 11, and the electrode pad 23, when viewed in a mount direction z of surface acoustic wave elements on the mount substrate 10. In the surface acoustic wave device of the first example, two surface acoustic wave elements 20 were flip-chip mounted on the mount substrate 10.

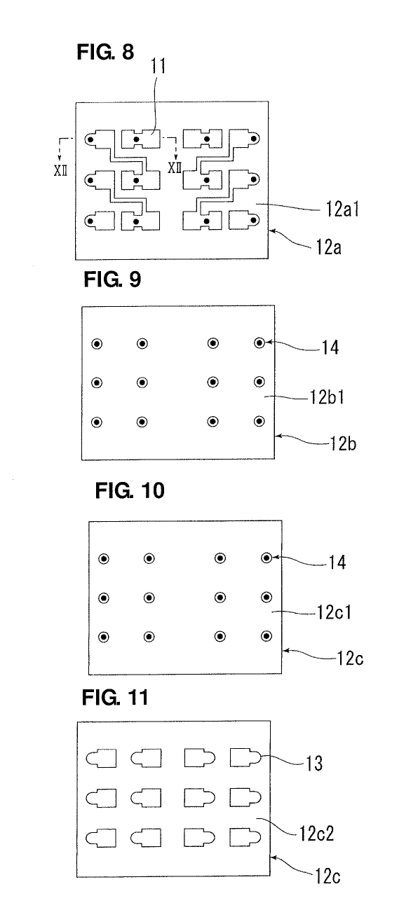

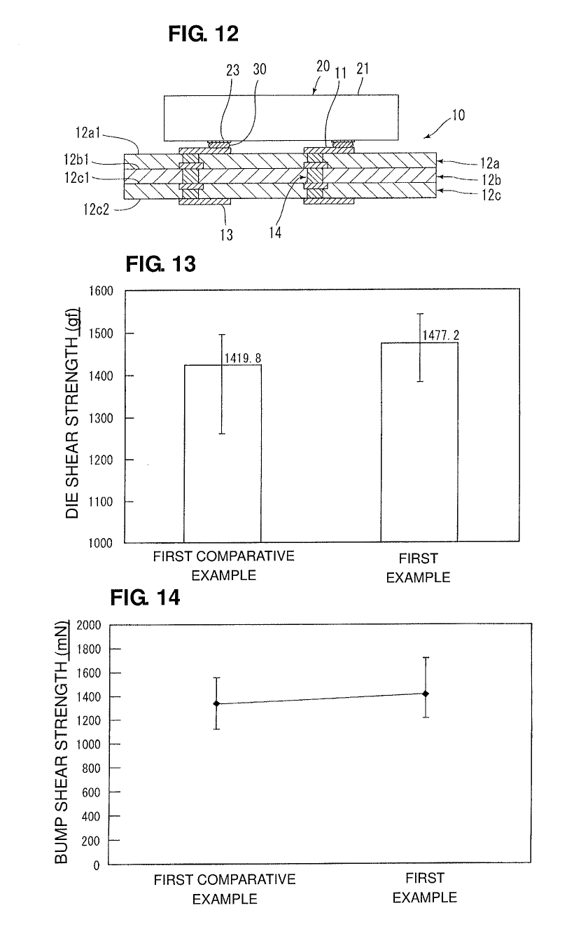

FIG. 8 is a schematic transparent plan view of a surface 12a1 of a first resin layer 12a of a mount substrate 10 in a surface acoustic wave device according to a first comparative example. FIG. 9 is a schematic transparent plan view of a surface 12b1 of a second resin layer 12b of the mount substrate 10 in the surface acoustic wave device of the first comparative example. FIG. 10 is a schematic transparent plan view of a surface 12c1 of a third resin layer 12c of the mount substrate 10 in the surface acoustic wave device of the first comparative example. FIG. 11 is a schematic transparent plan view of a surface 12c2 of the third resin layer 12c of the mount substrate 10 in the surface acoustic wave device of the first comparative example. FIG. 12 is a schematic sectional view of the surface acoustic wave device of the first comparative example, taken along line XII-XII of FIG. 8.

As the first comparative example, a surface acoustic wave device having structures illustrated in FIGS. 8 to 12 was prepared. As illustrated in FIGS. 8 and 12, the surface acoustic wave device of the first comparative example has a structure substantially similar to that adopted in the above-described surface acoustic wave device of the first example except that via-hole conductors are not provided below bumps 30 and the via-hole conductors are not provided below bonded portions of mount electrodes 11 and electrode pads 23 to the bumps 30.

FIG. 13 depicts die shear strengths of the surface acoustic wave device of the first example of a preferred embodiment of the present invention and the surface acoustic wave device of the first comparative example. FIG. 14 depicts bump shear strengths of the surface acoustic wave device of the first example of a preferred embodiment of the present invention and the surface acoustic wave device of the first comparative example. The die shear strength depicted in FIG. 13 is an average value of ten samples. The bump shear strength depicted in FIG. 14 is an average value of sixty bumps included in ten samples.

Here, the term “die shear strength” refers to a bonding strength (shear strength) between the surface acoustic wave element 20 and the mount substrate 10. The die shear strength was measured with a strength testing machine in a state in which the surface acoustic wave element 20 was flip-chip mounted on the die-attach surface 10a of the mount substrate 10 (a state in which the surface acoustic wave element 20 was not sealed by a sealing resin layer 40). Measurement with the strength testing machine was performed in conformity to standards MIL STD-883G, IEC 60749-19, and EIAJ ED-4703. In detail, first, a tool attached to a load sensor was moved down to the die-attach surface 10a of the mount substrate 10 in the strength test machine, and the strength testing machine detected the die-attach surface 10a of the mount board 10 and stopped the downward movement. Next, the tool was moved upward from the die-attach surface 10a of the mount board 10 to a set height, and the bonded portion between the surface acoustic wave element 20 and the mount substrate 10 was pressed to measure the load at the time of breaking.

The term “bump shear strength” refers to a bonding strength (shear strength) between one bump 30 and the mount substrate 10. The bump shear strength was measured with the same strength testing machine as for the die shear strength.

As is clear from FIG. 13, in the surface acoustic wave device of the first example, a die shear strength higher than in the surface acoustic wave device of the first comparative example was obtained. Further, as is clear from FIG. 14, in the surface acoustic wave device of the first example, a bump shear strength higher than in the surface acoustic wave device of the first comparative example was obtained. These results reveal that the surface acoustic wave element 20 and the mount substrate 10 are more firmly bonded in the surface acoustic wave device of the first example of a preferred embodiment of the present invention than in the surface acoustic wave device of the first comparative example. In other words, it is revealed that the surface acoustic wave element 20 and the mount substrate 10 can be firmly and securely bonded by placing the via-hole conductors below the bumps 30 and placing the via-hole conductors below the bonded portions of the mount electrodes 11 and the electrode pads 23 to the bumps 30.

In the above-described first preferred embodiment, the via-hole conductors preferably define portions of the line 14. However, the present invention is not limited thereto. For example, the via-hole conductors may be provided not to define portions of the line 14. Specifically, for example, the via-hole conductors may be arranged to be connected at one end to the line 14, but not to be connected at the other end to the line 14. Alternatively, the via-hole conductors may be provided separately from the line 14.

Modifications of the above-described first preferred embodiment and other preferred embodiments will be described below. In the following descriptions of the modifications and preferred embodiments, members having functions substantially similar to those in the first preferred embodiment are denoted by similar reference numerals, and descriptions thereof are skipped.

### First to Eighth Modifications

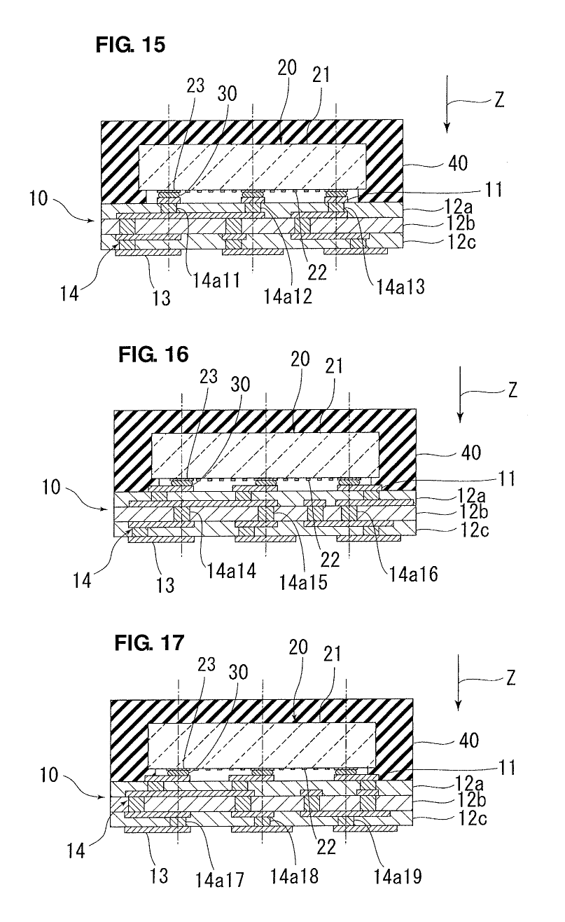

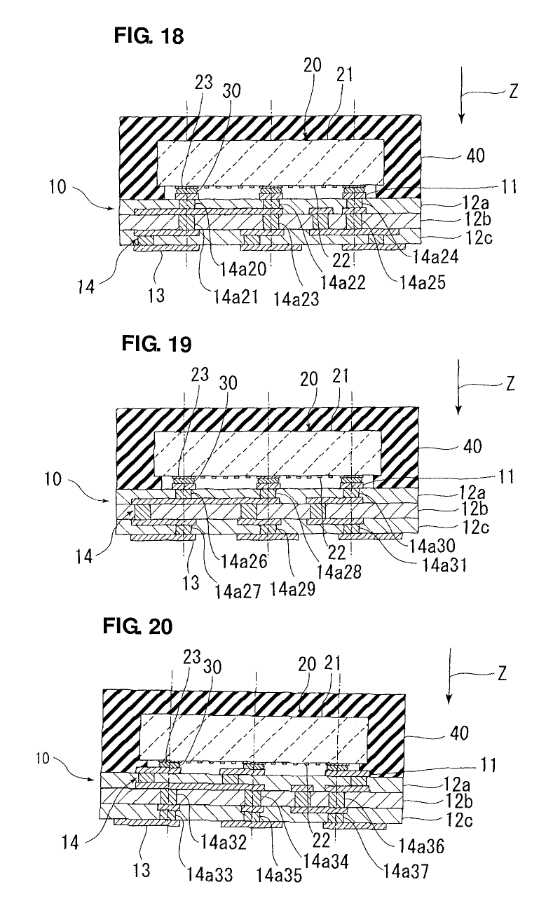

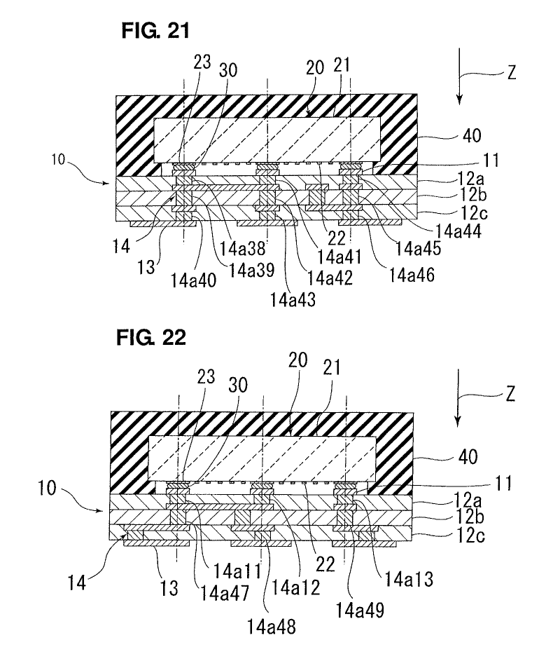

FIG. 15 is a schematic sectional view of a surface acoustic wave device according to a first modification of a preferred embodiment of the present invention. FIG. 16 is a schematic sectional view of a surface acoustic wave device according to a second modification of a preferred embodiment of the present invention. FIG. 17 is a schematic sectional view of a surface acoustic wave device according to a third modification of a preferred embodiment of the present invention. FIG. 18 is a schematic sectional view of a surface acoustic wave device according to a fourth modification of a preferred embodiment of the present invention. FIG. 19 is a schematic sectional view of a surface acoustic wave device according to a fifth modification of a preferred embodiment of the present invention. FIG. 20 is a schematic sectional view of a surface acoustic wave device according to a sixth modification of a preferred embodiment of the present invention. FIG. 21 is a schematic sectional view of a surface acoustic wave device according to a seventh modification of a preferred embodiment of the present invention. FIG. 22 is a schematic sectional view of a surface acoustic wave device according to an eighth modification of a preferred embodiment of the present invention.

An example of the structure of the line 14 in the first preferred embodiment has been described. However, in the present invention, the structures of the line and the via-hole conductors are not limited to those of the line and the via-hole conductors adopted in the first preferred embodiment. For example, when the mount substrate includes a plurality of resin layers, it is satisfactory as long as via-hole conductors provided in at least one of the resin layers are located below bumps and below bonded portions of mount electrodes and electrode pads to the bumps. Alternatively, when the mount substrate includes a plurality of resin layers, it is satisfactory as long as via-hole conductors provided in any of the resin layers are located below the bumps and the bonded portions of the mount electrode and the electrode pads to the bumps. In these structures, even when the via-hole conductors and the line have any structures, the surface acoustic wave element and the mount substrate can be bonded firmly.

For example, as in the first modification of a preferred embodiment of the present invention illustrated in FIG. 15, via-hole conductors 14a11 to 14a13 provided in a first resin layer 12a may be located below bumps 30 and below bonded portions of mount electrodes 11 and electrode pads 23 to the bumps 30. Further, as illustrated in FIG. 15, the via-hole conductors 14a11 to 14a13 may be aligned with the bumps 30, the mount electrodes 11, and the electrode pads 23, when viewed in a mount direction z of a surface acoustic wave element 20 on a mount substrate 10.

As in the second modification of a preferred embodiment of the present invention illustrated in FIG. 16, via-hole conductors 14a14 to 14a16 provided in a second resin layer 12b may be located below bumps 30 and below bonded portions of mount electrodes 11 and electrode pads 23 to the bumps 30. Further, as illustrated in FIG. 16, the via-hole conductors 14a14 to 14a16 may be aligned with the bumps 30, the mount electrodes 11, and the electrode pads 23, when viewed in a mount direction z of a surface acoustic wave element 20 on a mount substrate 10.

As in the third modification of a preferred embodiment of the present invention illustrated in FIG. 17, via-hole conductors 14a17 to 14a19 provided in a third resin layer 12c may be located below bumps 30 and below bonded portions of mount electrodes 11 and electrode pads 23 to the bumps 30. Further, as illustrated in FIG. 17, the via-hole conductors 14a17 to 14a19 may be aligned with the bumps 30, the mount electrodes 11, and the electrode pads 23, when viewed in a mount direction z of a surface acoustic wave element 20 on a mount substrate 10.

As in the fourth to sixth modifications of the present invention illustrated in FIGS. 18 to 20, via-hole conductors provided in two of first to third resin layers 12a to 12c may be located below bumps 30 and below bonded portions of mount electrodes 11 and electrode pads 23 to the bumps 30. Further, as illustrated in FIGS. 18 to 20, the via-hole conductors provided in two of the first to third resin layers 12a to 12c may be aligned with the bumps 30, the mount electrodes 11, and the electrode pads 23, when viewed in a mount direction z of a surface acoustic wave element 20 on a mount substrate 10. In this case, the surface acoustic wave element 20 and the mount substrate 10 can be bonded more firmly.

Specifically, in the fourth modification illustrated in FIG. 18, via-hole conductors 14a20, 14a22, 14a24 provided in a first resin layer 12a and via-hole conductors 14a21, 14a23, and 14a25 provided in a second resin layer 12b are located below bumps 30 and below bonded portions of mount electrodes 11 and electrode pads 23 to the bumps 30. Further, as illustrated in FIG. 18, the via-hole conductors 14a20 to 14a25 are aligned with the bumps 30, the mount electrodes 11, and the electrode pads 23, when viewed in a mount direction z of a surface acoustic wave element 20 on a mount substrate 10.

In the fifth modification illustrated in FIG. 19, via-hole conductors 14a26, 14a28, and 14a30 provided in a first resin layer 12a and via-hole conductors 14a27, 14a29, and 14a31 provided in a third resin layer 12c are located below bumps 30 and below bonded portions of mount electrodes 11 and electrode pads 23 to the bumps 30. Further, as illustrated in FIG. 19, the via-hole conductors 14a26 to 14a31 are aligned with the bumps 30, the mount electrodes 11, and the electrode pads 23, when viewed in a mount direction z of a surface acoustic wave element 20 on a mount substrate 10.

In the sixth modification illustrated in FIG. 20, via-hole conductors 14a32, 14a34, and 14a36 provided in a second resin layer 12b and via-hole conductors 14a33, 14a35, and 14a37 provided in a third resin layer 12c are located below bumps 30 and below bonded portions of mount electrodes 11 and electrode pads 23 to the bumps 30. Further, as illustrated in FIG. 20, the via-hole conductors 14a32 to 14a37 may be aligned with the bumps 30, the mount electrodes 11, and the electrode pads 23, when viewed in a mount direction z of a surface acoustic wave element 20 on a mount substrate 10.

As in the seventh modification illustrated in FIG. 21, via-hole conductors 14a38 to 14a46 provided in first to third resin layers 12a to 12c may be located below bumps 30 and below bonded portions of mount electrodes 11 and electrode pads 23 to the bumps 30. Further, as illustrated in FIG. 21, the via-hole conductors 14a38 to 14a46 may be aligned with the bumps 30, the mount electrodes 11, and the electrode pads 23, when viewed in a mount direction z of a surface acoustic wave element 20 on a mount substrate 10. In this case, the surface acoustic wave element 20 and the mount substrate 10 can be bonded more firmly.

As in the eighth modification illustrated in FIG. 22 serving as a further modification of the first modification, via-hole conductors 14a11 to 14a13 and 14a47 to 14a49 provided in first to third resin layers 12a to 12c may be located below bumps 30 and below bonded portions of mount electrodes 11 and electrode pads 23 to the bumps 30.

### Ninth and Tenth Modifications

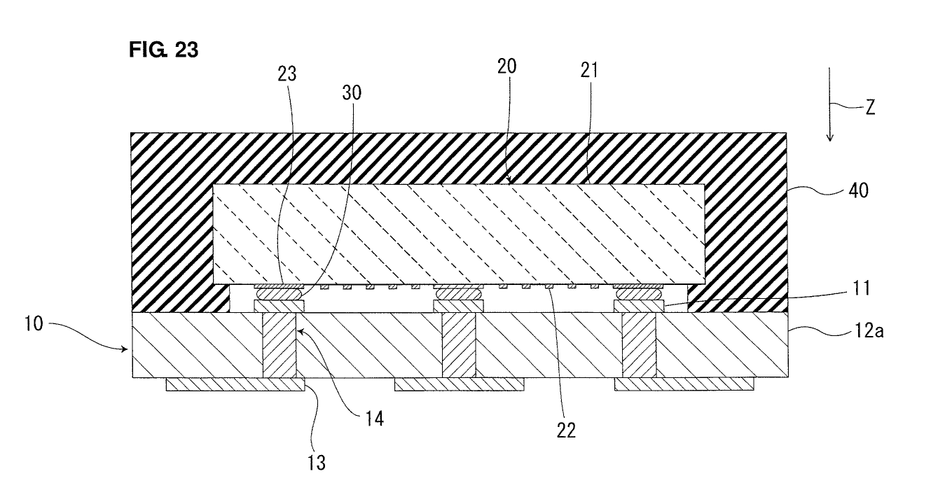

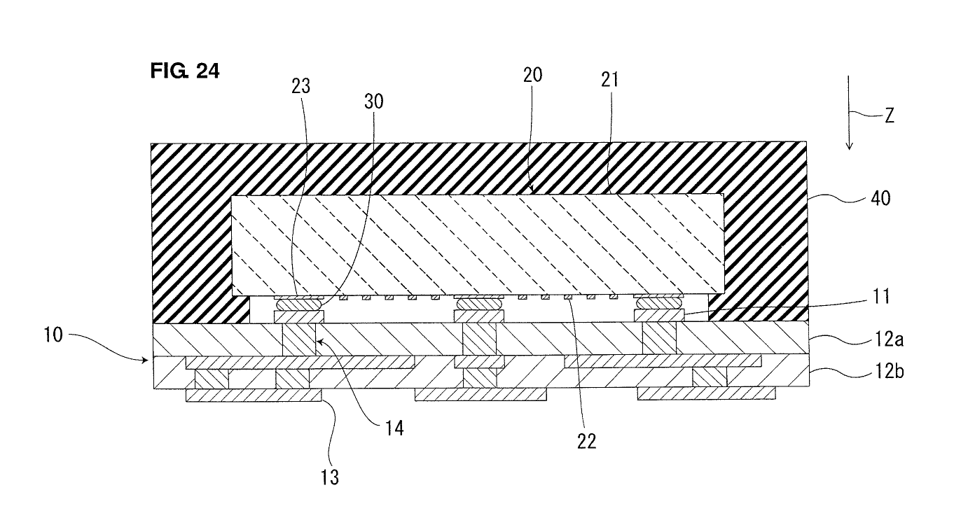

FIG. 23 is a schematic sectional view of a surface acoustic wave device according to a ninth modification of a preferred embodiment of the present invention. FIG. 24 is a schematic sectional view of a surface acoustic wave device according to a tenth modification of a preferred embodiment of the present invention. In the above-described first preferred embodiment, the mount substrate 10 preferably includes three resin layers. However, the present invention is not limited to this structure. For example, as in the ninth modification illustrated in FIG. 23, a mount substrate 10 may be a resin substrate including only one resin layer 12a. Further, as in the tenth modification illustrated in FIG. 24, a mount substrate 10 may be a resin substrate including a laminated body of two resin layers 12a and 12b. The mount substrate 10 may be a resin substrate including a laminated body of four or more resin layers. When a matching circuit, an LC resonant circuit, and an ESD (Electrostatic Discharge) protection circuit are incorporated in the mount substrate 10, the number of resin layers corresponds to the number of electrode layers necessary to provide these circuits. As long as the via-hole conductors are located below the bumps 30, that is, below the bonded portions of the mount electrodes 11 in the mount substrate 10 to the bumps 30, the number of resin layers provided in the mount substrate 10 is not limited.

In the modification illustrated in FIG. 23, a line 14 is formed in the mount substrate 10 by via-hole conductors extending in the mount direction z of a surface acoustic wave element 20 on the mount substrate 10.

### Second Preferred Embodiment

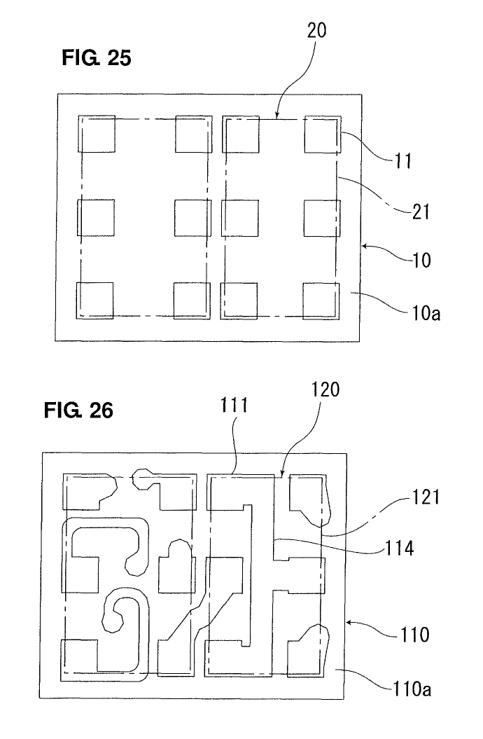

FIG. 25 is a schematic plan view of a die-attach surface 10a of a mount substrate 10 in a surface acoustic wave device according to a second preferred embodiment of the present invention. In FIG. 25, for convenience of explanation, members provided on the die-attach surface 10a other than mount electrodes 11 are not drawn, but only the mount electrodes 11 are drawn.

The surface acoustic wave device of the present preferred embodiment preferably has a configuration substantially similar to that adopted in the surface acoustic wave device 1 of the first preferred embodiment except for an electrode structure on the die-attach surface 10a of the mount substrate 10.

As illustrated in FIG. 25, in the surface acoustic wave device of the present preferred embodiment, a line 14 is not provided in an area of the die-attach surface 10a of the mount substrate 10 opposing a piezoelectric substrate 21 of a surface acoustic wave element 20, and only mount electrodes 11 are provided therein. In the surface acoustic wave device of the present preferred embodiment, the line 14 is provided in a portion of the die-attach surface 10a of the mount substrate 10 other than the area opposing the piezoelectric substrate 21 of the surface acoustic wave element 20. Specifically, the line 14 is provided inside the mount substrate 10.

FIG. 26 is a schematic plan view of a die-attach surface 110a of a mount substrate 110 in a surface acoustic wave device according to a reference example. For example, as in the reference example illustrated in FIG. 26, it is conceivable to form a portion of a line 114 together with mount electrodes 111 in an area of the die-attach surface 110a of the mount substrate 110 opposing a piezoelectric substrate 121 of a surface acoustic wave element 120, for example, in order to provide an inductance. However, when a portion of the line 114 is provided in the area of the die-attach surface 110a of the mount substrate 110 opposing the piezoelectric substrate 121 of the surface acoustic wave element 120, the mount substrate 110 formed by a resin substrate is sometimes deformed, for example, by external force applied to the surface acoustic wave device, thermal expansion of the mount substrate formed by the resin substrate due to the temperature at which the surface acoustic wave element is flip-chip mounted on the mount substrate, and the load applied to the surface acoustic wave element when the surface acoustic wave element is flip-chip mounted on the mount substrate. When the mount substrate 110 formed by the resin substrate deforms, a portion of the line 114 provided in the area of the die-attach surface 110a of the mount substrate 110 opposing the piezoelectric substrate 121 of the surface acoustic wave element 120 sometimes touches an IDT electrode and the like on the surface acoustic wave element, and this scratches the IDT electrode and the like.

In contrast, in the surface acoustic wave device of the present preferred embodiment, the line 14 is not provided in the area of the die-attach surface 10a of the mount substrate 10 opposing the piezoelectric substrate 21 of the surface acoustic wave element 20. On the die-attach surface 10a, the mount electrodes 11 are only provided. For this reason, the above-described problem of scratching the IDT electrode and the like can be prevented effectively.

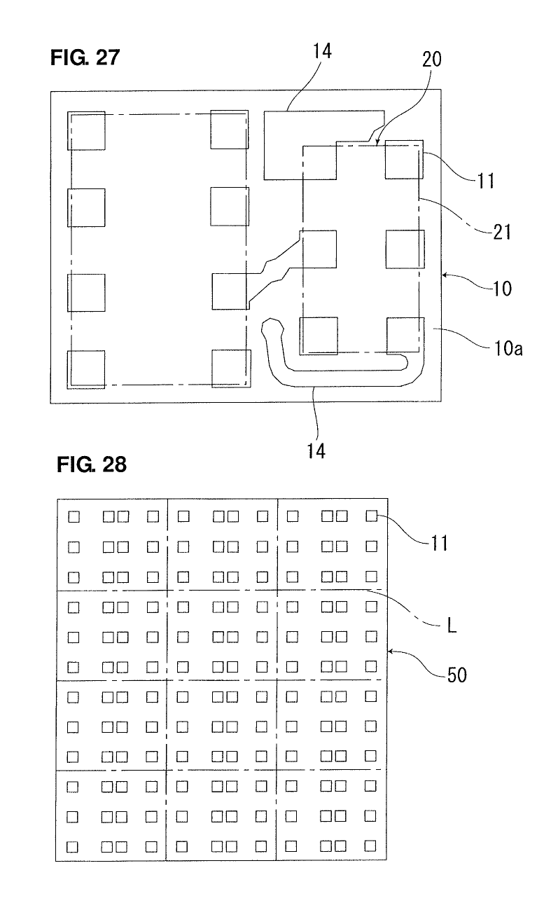

FIG. 27 is a schematic plan view of a die-attach surface 10a of a mount substrate 10 in a surface acoustic wave device according to an eleventh modification of a preferred embodiment of the present invention. As in the eleventh modification illustrated in FIG. 27, no line 14 may be provided in an area of the die-attach surface 10a of the mount substrate 10 opposing a piezoelectric substrate 21 of a surface acoustic wave element 20, and only mount electrodes 11 may be provided therein. A portion of the line 14 may be provided in an area that does not oppose the piezoelectric substrate 21 of the surface acoustic wave element 20.

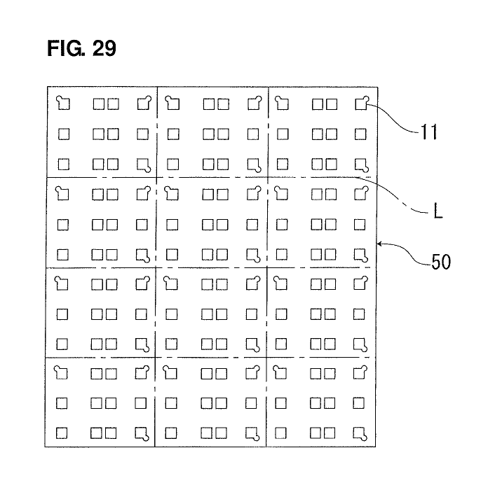

For example, the mount substrate 10 is preferably produced by cutting a motherboard 50 illustrated in FIG. 28 along dicing lines L into a plurality of mount substrates. FIG. 28 is a schematic plan view of the motherboard 50 for producing the mount substrate 10 in the surface acoustic wave device of the second preferred embodiment. In particular, the mount substrate 10 is preferably produced by cutting the motherboard 50 along the dicing lines L into a plurality of mount substrates after flip-chip mounting of the surface acoustic wave element 20. This is because multiple surface acoustic wave devices can be thereby produced efficiently. However, when a plurality of mount electrodes 11 are symmetrically arranged on the die-attach surface 10a and the mount board 10 is produced by cutting the motherboard 50 of FIG. 28 into a plurality of mount substrates after flip-chip mounting of the surface acoustic wave element 20, as in the surface acoustic wave device of the present preferred embodiment, it is difficult to identify the direction of the mount substrate 10 when the surface acoustic wave element 20 is flip-chip mounted thereon. For this reason, at least one of the mount electrodes 11 preferably has an asymmetric shape, as in a motherboard 50 illustrated in FIG. 29. FIG. 29 is a schematic plan view of the motherboard 50 for producing mount substrates 10 in a surface acoustic wave device according to a twelfth modification of a preferred embodiment of the present invention. This structure can enhance the ability to identify the direction of the mount substrate 10 when the surface acoustic wave element is flip-chip mounted. Therefore, mounting of the surface acoustic wave element 20 is facilitated.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A surface acoustic wave device comprising:
a surface acoustic wave element including a plurality of electrode pads; and
a mount substrate including a die-attach surface on which the surface acoustic wave element is flip-chip mounted by bumps made of Au; wherein
the mount substrate includes:
at least one resin layer including via-holes;
a plurality of mount electrodes provided on the die-attach surface of the mount substrate and bonded to the electrode pads by the bumps; and
via-hole conductors provided in the via-holes; and
at least one of each of the electrode pads and each of the mount electrodes includes a front layer made of Au, and at least one of the via-hole conductors is located below the bump.

2. The surface acoustic wave device according to claim 1, wherein at least one of the via-hole conductors is located below a bonded portion between the corresponding mount electrode and the corresponding electrode pad to the bump.

3. The surface acoustic wave device according to claim 1, wherein at least one of the via-hole conductors is aligned with the bump, the corresponding mount electrode, and the corresponding electrode pad, when viewed in a mount direction of the surface acoustic wave element on the mount substrate.

4. The surface acoustic wave device according to claim 1, wherein the mount substrate includes a plurality of terminal electrodes provided on a surface of the mount substrate other than the die-attach surface, and a line that connects the mount electrodes and the terminal electrodes, and the via-hole conductors define a portion of the line.

5. The surface acoustic wave device according to claim 1, wherein the resin layer is made of a resin composition containing resin, and a glass transition temperature of the resin is within a range of about 100° C. to about 300° C.

6. The surface acoustic wave device according to claim 1, wherein the resin layer is a glass epoxy resin layer made of glass epoxy in which a glass woven cloth is impregnated with epoxy resin.

7. The surface acoustic wave device according to claim 1, wherein the mount electrodes are made of Au, and each of the mount electrodes includes a laminated body including an Au layer that defines a front layer and a Ni layer made of Ni.

8. The surface acoustic wave device according to claim 7, wherein the laminated body includes a plurality of plated layers containing the Ni layer, and the Ni layer has a largest thickness among the plated layers.

9. The surface acoustic wave device according to claim 1, wherein the via-hole conductors are made of Cu.

10. The surface acoustic wave device according to claim 1, wherein the mount substrate includes a plurality of terminal electrodes provided on a surface of the mount substrate other than the die-attach surface, and a line that connects the mount electrodes and the terminal electrodes, and the line is provided in a portion of the die-attach surface of the mount substrate other than an area opposing a piezoelectric substrate of the surface acoustic wave element.

11. The surface acoustic wave device according to claim 1, further comprising a sealing resin layer provided on the mount substrate to seal the surface acoustic wave element.

12. The surface acoustic wave device according to claim 1, wherein the mount substrate includes a plurality of resin layers, the via-hole conductors are provided in at least one of the resin layers and are located below the bumps and below bonded portions of the mount electrodes and the electrode pads to the bumps.

13. The surface acoustic wave device according to claim 12, wherein the via-hole conductors are aligned with the bumps, the mount electrodes and the electrode pads when viewed in a mount direction of the surface acoustic wave element on the mount substrate.

14. The surface acoustic wave device according to claim 1, wherein the mount substrate includes a plurality of resin layers, the via-hole conductors are provided in the plurality of resin layers and are located below the bumps and below bonded portions of the mount electrodes and the electrode pads to the bumps.

15. The surface acoustic wave device according to claim 14, wherein the via-hole conductors are aligned with the bumps, the mount electrodes and the electrode pads when viewed in a mount direction of the surface acoustic wave element on the mount substrate.

16. The surface acoustic wave device according to claim 1, wherein the mount substrate includes only the at least one resin layer.

17. The surface acoustic wave device according to claim 1, wherein mount substrate includes a plurality of resin layers.

18. The surface acoustic wave device according to claim 1, wherein the surface wave device is a Chip Size Package device.

19. A production method for the surface acoustic wave device according to claim 1, wherein the surface acoustic wave element is flip-chip mounted on the mount substrate by applying a load to the surface acoustic wave element in a direction to bring the mount substrate and the surface acoustic wave element closer to each other and applying ultrasonic waves to the surface acoustic wave element while heating the bumps and the mount electrodes, or the bumps and the electrode pads in a state in which the bumps are in contact with the mount electrodes or the bumps are in contact with the electrode pads.

20. The production method for the surface acoustic wave device according to claim 19, wherein the bumps and the mount electrodes, or the bumps and the electrode pads are heated to a temperature higher than or equal to a recrylstallization temperature of Au when the surface acoustic wave element is flip-chip mounted on the mount substrate.
